(19) United States
(12) Patent Application Publication
(10) Pub. No.: US 2024/0153804 A1
(43) Pub. Date: May 9, 2024

(54) Handling device for transporting interface units for a test device for testing semiconductors

(71) Applicant: Turbodynamics GmbH, Stephanskirchen (DE)

(72) Inventors: Stefan Thurmaier, Bad Aibling (DE); Norbert Hunger, Stephanskirchen (DE)

(21) Appl. No.: 18/504,216

(22) Filed: Nov. 8, 2023

(30) Foreign Application Priority Data
Nov. 8, 2022 (DE) 10 2022 129 458.7

(51) Int. Cl. H01L 21/677; G01R 31/26

(52) U.S. Cl. CPC H01L 21/67712; G01R 31/2601; H01L 21/67766; H01L 21/67775

(57) ABSTRACT

The invention relates to a handling device for transporting interface units for a test device for testing semiconductors. The handling device comprises a travel mechanism with a drive unit or a coupling unit for coupling to such a travel mechanism, which is designed for travelling on a substantially flat surface, a gripping device for gripping and holding an interface unit, and a docking unit for coupling to a corresponding counter-docking unit.

The invention relates to a handling device for transporting interface units for a test device for testing semiconductors.

Such a handling device, with which interface units can be transported back and forth between a storage device and a test device for testing printed circuit boards, is shown in DE 10 2020 104 641 A1. The handling device is an independently travelling vehicle 43 that has docking elements which can be used to couple the handling device both to the storage device and to a test device.

Docking elements of this type are known, for example, from U.S. Pat. No. 7,382,145 B2.

In the yet to be published German patent application DE 10 2021 114 564.3, a further handling device is shown which has docking elements which can contract independently, whereby the docking elements arranged on the handling device are automatically aligned axially to the corresponding counter-docking elements. By using two such docking elements and counter-docking elements, a correspondingly coupled handling device is clearly defined in space in relation to the corresponding counter device.

An interface unit is a type of adapter with one or more contact fields with which a semiconductor to be tested is contacted. The semiconductor can be a semiconductor component or a wafer. In order to test different semiconductor components or wafers with a test device, the interface units must be exchanged accordingly. Such an interface unit is a multilayer printed circuit board with a large number of spring contact elements. Depending on its complexity, such an interface board costs up to USD 500,000. Damage to such an interface board represents an immediate economic loss and can also lead to consequential damage if a certain type of semiconductor or wafer cannot be tested in production. It is therefore extremely important that the interface units are replaced and stored without damage. The interface units can also weigh up to 40 kg, which makes mechanical handling virtually impossible for ergonomic reasons.

EP 2 587 272 A2 describes a trolley with a travel mechanism designed for transporting interface units. This trolley has a swivelling robot arm that can be supported on the ground by a corresponding support unit. A holding unit can be lowered and raised again from a free end of the robot arm by means of three cables. The holding unit has guide elements with corresponding guide openings so that the holding unit is positioned as correctly as possible on a tester in order to transfer an interface unit.

US 2003/0178987 A1 shows another trolley that can be coupled to a corresponding device by means of corresponding latching and guide elements for transferring an interface unit.

DE 10 2008 044 756 A1 discloses a manipulator for moving heavy loads, such as test heads for integrated circuits. This manipulator is to display elasticity in a drive train and be designed to save space despite a large spring travel.

The invention is based on the task of further developing the handling device described above in such a way that an interface element can be transferred or picked up very precisely in a simple manner.

A further task of the present invention is to further develop a handling device described above in such a way that a reliable and precise transfer or pick-up of an interface unit is possible even on uneven surface.

One or more of the tasks are solved by a handling device as defined in the independent patent claims. Advantageous embodiments of the handling device are given in the respective subclaims.

A first aspect of the present invention, envisions a handling device for transporting interface units for a test device for testing semiconductors. The handling device comprises a travel mechanism with a drive unit or a coupling unit for coupling to such a travel mechanism, which is designed for travelling on a substantially flat surface, a gripping device comprising a gripping element guide unit and a gripping element for gripping and holding an interface unit, whereby the gripping element can be lowered or raised by the gripping element guide unit, and a docking unit for coupling the gripping element guide unit to a corresponding counter-docking unit.

This handling device is characterised by the fact that the gripping element guide unit of the handling device is mounted by means of a swivel joint.

The swivel joint is mounted at one point and is designed to swivel freely in all directions. The swivel joint is preferably a spherical joint or a ball joint. However, it can also be a flexible body, such as a rod, or a flexible spring that can be bent in all directions.

The gripping element guide unit of the handling device is mounted by means of the swivel joint. This allows the gripping element guide unit, together with an interface unit held by the gripping element, to be guided in space with a different inclination in relation to the rest of the handling device. This means that the interface unit can always be held in a horizontal position, even if the handling device is moving on an uneven surface.

As the docking unit is designed for coupling the gripping element guide unit to a corresponding counter-docking unit, it is also mounted by means of the swivel joint and can be coupled to a counter-docking unit with different inclinations in relation to the rest of the handling device. This allows the docking unit of the handling device to be coupled to the counter-docking unit without exerting tension on the handling device. The docking unit can thus automatically align itself with the counter-docking unit during the docking process. This is very advantageous, as it means that the gripping device, when connected to the docking unit, can also be precisely aligned in relation to the counter-docking unit. The counter-docking unit is rigidly attached to a further device, such as a storage device for storing interface units or a test device for testing semiconductors, and is precisely aligned with respect to this device, whereby when the handling device is coupled, it is precisely aligned with respect to the storage device or the test device, whereby the alignment is essentially stress-free.

In contrast, the document EP 2 587 272 A2 shows a device in which docking elements are provided on a gripping element. The docking elements are not arranged on a gripping element guide unit, which is additionally mounted on a handling device by means of a swivel joint, whereby the gripping element can be lowered or raised by the gripping element guide unit. According to the invention, the pivotably mounted gripping element guide unit is fixed by means of the docking unit, which automatically aligns the gripping element guide unit, allowing the gripping element to be lowered reliably and precisely so that the desired transfer location for transferring the interface unit is reached.

The docking unit preferably has two docking elements that are spaced slightly apart. As a result, the docking unit coupled to the counter-docking unit is precisely aligned in the plane defined by the corresponding counter-docking elements of the counter-docking unit.

The docking elements are preferably designed in such a way that when they engage with corresponding counter-docking elements, a counter-docking unit is aligned in the axial direction to the counter-docking elements. The axial direction is the direction in which the docking elements and the counter-docking elements are moved in relation to each other during the coupling or docking process. Aligning the docking elements with the counter-docking elements in the axial direction means that the position and orientation of the docking elements in space is clearly defined in relation to the counter-docking elements or counter-docking unit.

The docking elements can be designed in such a way that when they engage with corresponding counter-docking elements of a counter-docking unit, they are drawn into the counter-docking elements in the axial direction up to a predetermined setting. As a result, the handling device can initially be coupled to the counter-docking unit with a certain amount of play with the docking unit, whereby the docking unit and the counter-docking unit are then drawn together essentially without play, whereby the docking elements of the docking unit are positioned exactly in relation to the counter-docking elements of the counter-docking unit. It is therefore sufficient to first position the handling device roughly, whereby the fine positioning is then carried out by drawing the docking elements and the counter-docking elements together.

The handling device can have a lifting mechanism with which the docking unit and the gripping device on the handling device can be raised or lowered. This makes it possible to couple the handling device to different counter-docking units, which can be arranged at different heights. In addition, any tolerances in the vertical position of the counter-docking unit can be compensated for.

The handling device can be equipped with a camera for spatial vision and a control device with which the handling device can automatically approach a device with a counter-docking unit so that the docking unit and the counter-docking unit can engage with each other. If the docking elements and the counter-docking elements are designed to draw themselves together, as explained above, then only a rough positioning of the handling device with respect to the counter-docking unit needs to be carried out by the control device.

According to a further aspect of the present invention, a handling device for transporting interface units is provided for a test device for testing semiconductors, which comprises a gripping device for gripping and holding an interface unit, whereby the gripping device has a gripping element movable in the vertical direction for gripping an interface unit. The handling device is characterised by the gripping device having a cable pull with which the gripping element can be lowered or raised.

Because the gripping element can be raised and lowered by means of a cable pull, an interface unit held by the gripping element is deposited without pressure, i.e., by its weight alone, on a device in which the interface unit is to be picked up. Such a device is typically a test device for testing semiconductors or a storage device for holding a large number of such interface units. The “pressureless” depositing of an interface unit ensures that the interface unit is not damaged when the interface unit is transferred from the handling device to another device. Since such interface units are extremely sensitive, such a safe, damage-free transfer to an interface unit is a significant advantage over conventional handling devices.

The cable pull can be designed with a commercially available cable, such as a steel or plastic cable. Instead of a cable, however, the cable pull can also be designed with a belt. The use of a belt has the advantage that, unlike a cable, in particular a steel cable, a belt produces hardly any abrasion and is therefore suitable for use in a clean room.

The term “cable pull” does not mean that the cable pull has a transmission ratio, but that the interface unit is raised or lowered by a cable alone.

The gripping device can comprise the lowerable gripping element and a stationary gripping element guide unit, whereby the lowerable gripping element has at least one guide rod which engages in a corresponding guide hole in the gripping element guide unit. As a result, when the lowerable gripping element is lowered or raised, it is guided precisely along one direction. Preferably, several, in particular three or four guide rods are provided, which are at the same time attached to the lowerable gripping element and are each guided through a corresponding guide hole on the gripping element guide unit.

The docking unit of the handling device is preferably attached to the gripping element guide unit and the gripping element guide unit is mounted on the rest of the handling device by means of the swivel joint. In this way, when the docking unit is coupled with a corresponding counter-docking unit, the gripping element guide unit is automatically aligned exactly with respect to the counter-docking unit and thus exactly with respect to the device to which the counter-docking unit is attached. This can ensure that the gripping element guide unit is aligned exactly parallel to a receiving surface to accept the interface unit, which is provided on the device to which the interface unit is to be transferred by the handling device. Such a device is typically a test device or a storage device, as already explained above.

The gripping device is preferably designed in such a way that the gripping element rests against the gripping element guide unit in the maximum position achieved by the cable pull. This means that the gripping element is firmly coupled to the gripping element guide unit and the distance to the swivel joint is minimised, which reduces the risk of subjecting the interface unit to strong vibrations when moving the handling device.

The gripping element can have a gripper that can be actuated by means of an actuator. The actuator can, for example, be controlled via a radio interface, a cable connection, or a Bowden cable. If the actuator can be controlled by means of a radio interface, it is useful if the gripping element has a rechargeable battery that provides the corresponding power supply for operating the actuator and the radio interface.

The aspects explained above can also be provided in combination on a handling device.

Furthermore, the invention provides a method for picking up an interface unit from a test device for testing semiconductors with a handling device as explained above, comprising the following steps, Approach of the handling device to the test device, coupling of docking elements of the handling device to counter-docking elements of the test device, gripping of an interface unit by means of grippers arranged on a gripping element of the handling device, and removal of the handling device with an interface unit mounted on it.

In addition, the invention also provides a method for transferring an interface unit arranged on a gripping element of a handling device to a test device for testing semiconductors with a handling device explained above, comprising the following steps:
Approach of the handling device to the test device, coupling of the docking elements of the handling device to counter-docking elements of the test device, depositing of an interface unit by means of grippers arranged on the gripping element, and free movement of the handling device.

The advantages described above with reference to the handling device apply analogously to the method according to the invention.

The invention is explained in more detail below by way of example with reference to the drawings. The drawings show in:

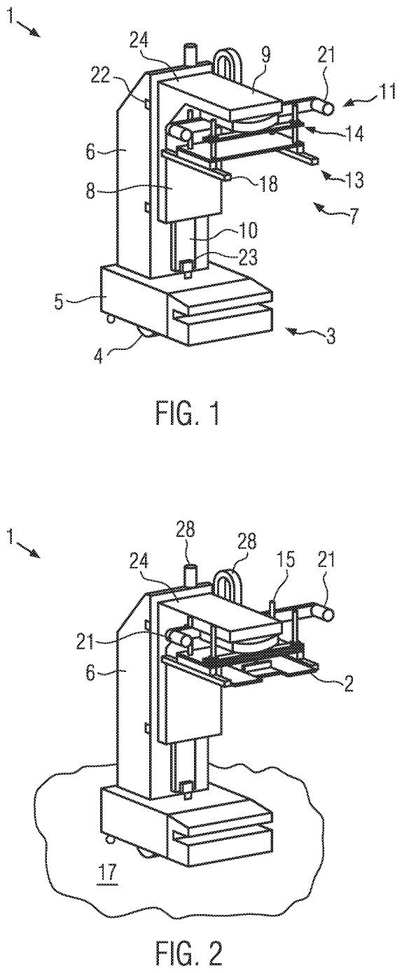

FIG. 1 a (schematic) representation of a handling device according to the invention in an oblique perspective view from the front,

FIG. 2 a (schematic) representation of the handling device according to the invention with an interface unit in a perspective view from the front,

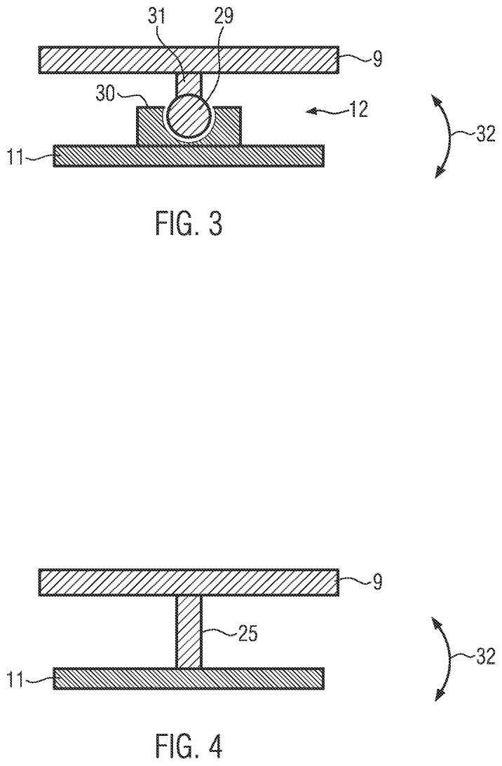

FIG. 3 a schematic sectional view of a swivel joint of the handling device according to the invention,

FIG. 4 a schematic sectional view of a flexible body or a flexible spring of the handling device according to the invention,

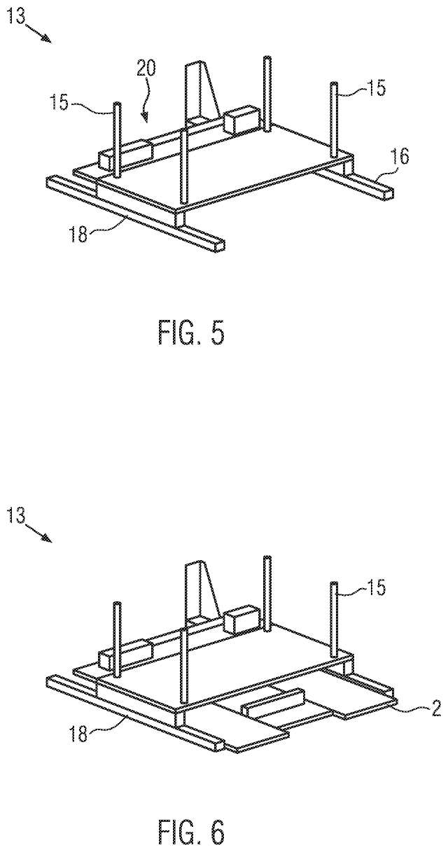

FIG. 5 a (schematic) representation of a gripping element of the handling device according to the invention in a perspective view from the front,

FIG. 6 a (schematic) representation of the gripping element of the handling device according to the invention as shown in FIG. 5 with an interface unit in an oblique perspective view from the front,

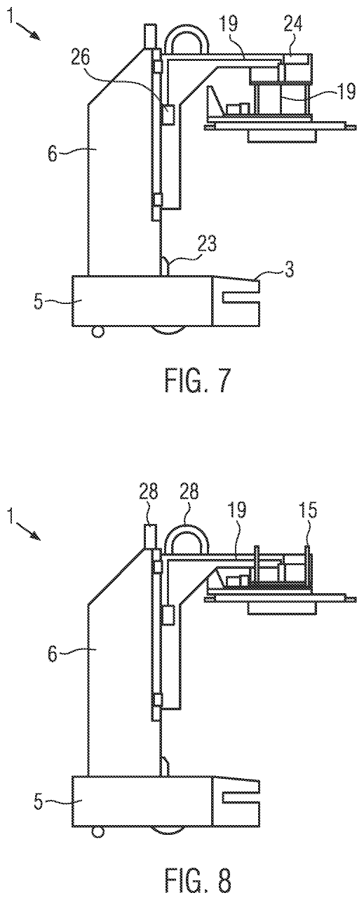

FIG. 7 a (schematic) representation of the handling device according to the invention with a cable pull in a first position in a partially sectioned side view, and

FIG. 8 a (schematic) representation of the handling device according to the invention with the cable pull in a second position in a partially sectioned side view.

In the following, a handling device 1 according to the invention for transporting interface units 2 between a storage device (not shown) and a test device (not shown) for testing semiconductors is described in more detail with reference to an embodiment example (FIGS. 1 to 8).

The storage device and the test device are described in detail in the patent applications DE 10 2013 109 055 A1, DE 10 2012 103 893 A1, DE 10 2012 112 271 A1, DE 10 2016 102 836 A1, DE 10 2017 104 516 A1, DE 102 019 119 134 A1, DE 10 2020 104 641 A1, to which reference is hereby made in full.

The handling device 1 comprises a base 5 in the lower portion. The base 5 is an essentially U-shaped receiving body with a closed rear side, which has a coupling unit with means of coupling on the inside for coupling to a travel mechanism 3. The travel mechanism 3 is, for example, an AGV (automated guided vehicle) or an AMR (autonomous mobile robot) and can be inserted into the receiving body of the base 5 and precisely accepted by it. The travel mechanism 3 can be fixed in a detachable manner in the base 5 by the means of coupling.

The travel mechanism 3 is used to move the handling device 1 and is designed to travel on an essentially flat surface 17. The handling device 1 can be moved freely on the surface 17 by means of the travel mechanism 3. For this purpose, the travel mechanism 3 has wheels 4 at the end facing the ground 17, which are connected to a drive unit. The drive unit is provided with a control device for controlling the wheels 4.

Furthermore, the travel mechanism 3 has, for example, a camera for spatial vision in order to be able to orientate itself in space. Strips can also be provided on the ground surface 17, which the travel mechanism 3 can use to orientate itself by means of a camera attached to the underbody of the travel mechanism 3. The strips then indicate the exact path along which the travel mechanism 3 should move. Conductive wires can also be inserted into the ground 17, which can be recognised by the travel mechanism 3 by means of radio waves and induction. The wires can then also define the path along which the travel mechanism 3 should move or, in addition to navigation with the camera, mark out an area that the travel mechanism 3 should not leave.

The travel mechanism 3 preferably has a radio or data interface with which signals can be received. The signals can be used to transmit a new destination to the travel mechanism 3 or to stop it. A transportable remote control can also be provided, for example, so that the travel mechanism 3 can be controlled manually by a user.

A base body 6 of the handling device 1 is provided on the base 5, which protrudes upwards on the base 5 like a column.

A lifting device 24 is provided on the base body 6. The lifting device 24 has a vertical leg 8 and a horizontal leg 9, with the horizontal leg 9 projecting forwards from the base body 6 when viewed in the direction of travel. The vertical leg 8 of the lifting device 24 can be moved along the base body 6.

For this purpose, the lifting device 24 is connected to the base body 6 by means of the vertical leg 8, whereby the base body 6 has a vertical rail 10 in which the vertical leg 8 is guided vertically by means of a lifting mechanism 27 (not shown) and can be moved. Furthermore, several guide elements 22 are arranged laterally on the vertical leg 8 in order to guide the vertical leg 8 on the base body 6.

A stopper element 23 is provided on the travel mechanism 3 in a lower area adjacent to the base body 6. The stopper element 23 serves as a stop against which the vertical leg 8 rests in the lowest position of the lifting device 24.

The lifting mechanism 27 has tracks 28 for guiding cables from the base body 6 to the lifting device 24 in order to supply the lifting device 24 with power and, if necessary, to provide a data connection.

At an upper end of the vertical leg 8 of the lifting device 24, the horizontal leg 9 projects away from the base body 6 like an arm. At an end of the horizontal leg 9 remote from the base body 6, the lifting device 24 has a gripping device 7.

The gripping device 7 comprises a gripping element guide unit 11 and a gripping element 13. The gripping element guide unit 11 is connected to the lifting device 24 by means of a swivel joint 12 (see FIG. 3). In the present embodiment example, the swivel joint 12 is a ball joint or a spherical joint and comprises a bearing ball 29, a bearing body 30 and a bearing stub 31, on which the bearing ball 29 is arranged. The bearing body 30 essentially surrounds the bearing ball 29 in a form-fitting manner and is rotatably mounted on it. By means of the swivel joint 12, the gripping element guide unit 11 and thus the entire gripping device 7 is mounted around a point and is designed to swivel freely in all spatial directions 32. Thus, the gripping element guide unit 11 together with the gripping element 13 always tends to swivel into a horizontal position and remain in this position, even if the surface 17 on which the handling device 1 is currently moving is inclined and the handling device 1 is in an inclined position for this reason.

The swivel joint 12 can also be a flexible body or a flexible spring 25, for example, which can be bent in all spatial directions 32 (see FIG. 4).

The gripping element guide unit 11 is used to guide the gripping element 13. For this purpose, the gripping element guide unit 11 has vertically arranged guide holes 14 at approximately the height of the swivel joint 12, into which corresponding vertical guide rods 15 of the gripping element 13 can engage and are guided. The gripping element 13 is coupled to the gripping element guide unit 11 by means of the guide rods 15 and, like the gripping element guide unit 11, is subject to the swivelling movements of the swivel joint 12. The guide rods 15 are freely movable in the vertical direction within the guide holes 14. The guide holes 14 are distributed on the gripping element guide unit 11 and are preferably spaced as far apart as possible. Preferably, the gripping element guide unit 11 has one guide hole 14 in each of its corner areas.

The gripping element 13 (FIGS. 5 and 6) is used to grip and hold an interface unit 2. An interface unit 2 is an essentially rectangular plate with various contact elements, which can also be designed as spring contacts (pogo pins).

The gripping element 13 has grippers 16 for gripping and holding an interface unit 2. The grippers 16 are mechanical grippers that are arranged, for example, in a lateral area of the gripping element 13 and laterally grip an interface unit 2 in order to detachably couple the interface unit 2 to the gripping element 13. For example, a magnetic connection can also be provided, with which the grippers 16 couple an interface unit 2 to the gripping element 13, or other mechanical coupling elements that engage in recesses of the interface unit 2, for example. A combination of different coupling elements can also be provided.

In order to support and protect an interface unit 2 laterally, the gripping element 13 has guide rails 18.

To actuate the grippers 16, the gripping element 13 has an actuator 20. The actuator 20 can be controlled via a radio interface, a cable connection, or a Bowden cable, for example.

The gripping element guide unit 11 has a cable feed device with a cable 19 and an actuating device 26 for lowering and retracting the cable 19 (FIGS. 7 and 8). The cable 19 extends from an upper area of the vertical leg 8 of the lifting device 24 to a central area of the gripping element 13, where it is connected to the gripping element 13. The cable 19 runs from the vertical leg 8 to a central area of the gripping element guide unit 11 within the lifting device 24. The cable 19 runs freely from the central area of the gripping element guide unit 11 to the central area of the gripping element 13.

Inside the vertical leg 8, the cable 19 is connected to the actuating device 26. The actuating device 26 is a lifting cylinder with an electric drive, but can also be a drum for winding or unwinding the cable 19.

The cable 19 can be used to raise or lower the gripping element 13 together with an interface unit 2. The maximum distance that the gripping element 13 can be lowered must not exceed the length of the guide rods 15, which should remain in contact with the guide holes 14 of the gripping element guide unit 11 at all times.

The cable 19 can be a commercially available cable, such as a steel or plastic cable. However, the cable 19 can also be a belt. The use of a belt has the advantage that, unlike a cable, in particular a steel cable, a belt produces hardly any abrasion and is therefore suitable for use in a clean room.

Because the gripping element 13 can be raised and lowered by means of the cable pull 19, an interface unit 2 is deposited without pressure, i.e., by its weight alone. The “pressureless” depositing of an interface unit 2 ensures that the interface unit 2 is not damaged when the interface unit 2 is transferred from the handling device 1 to another device.

A docking unit is provided on the gripping element guide unit 11. The docking unit comprises a docking element 21 laterally at approximately the same height as the swivel joint 12 and at a distance from it and on both sides. The docking elements 21 are used for positionally accurate coupling to corresponding counter-docking elements of a counter-docking unit of a storage device or a test device.

For this purpose, a camera can be provided on the gripping element guide unit 11 of the gripping device 7 so that the handling device 1 independently finds the correct distance to a storage device or a test device and independently positions the docking elements 21 exactly in relation to the counter-docking elements of the storage device or the test device.

The docking elements 21 and the counter-docking elements are designed according to the plug/socket principle, with the docking elements 21 forming the plugs and the counter-docking elements forming the sockets. The docking elements 21 have a front section that is preferably conical in shape. A cylindrical design or any other shape that allows exact positioning is also possible. Such docking elements and counter-docking elements are described in detail in DE 10 2013 109 055 A1.

The docking elements 21 are designed in such a way that when they engage with the corresponding counter-docking elements of the counter-docking unit, they align themselves in an axial direction to the counter-docking elements. The axial direction is the direction in which the docking elements 21 and the counter-docking elements are moved relative to each other during the coupling or docking process. Aligning the docking elements 21 with the counter-docking elements in the axial direction means that the position and orientation of the docking elements 21 in space is clearly defined with respect to the counter-docking elements.

In addition, the docking elements 21 are designed in such a way that when they engage with the corresponding counter-docking elements of the counter-docking unit, they are drawn into the counter-docking elements in the axial direction up to a predetermined end position. As a result, the handling device 1 can initially be coupled with the docking unit to the counter-docking unit with a certain amount of play, whereby the docking unit and the counter-docking unit are then drawn together essentially without play, whereby the docking elements 21 are positioned precisely in relation to the counter-docking elements. It is therefore sufficient to first position the handling device 1 roughly, whereby the fine positioning is then carried out by pulling the docking elements 21 and the counter-docking elements together.

The handling device 1 can have a radio interface with which signals can be received. The signals can be used to actuate the lifting mechanism 27 and/or to move the cable 19 of the cable pulling device. For example, a transportable remote control can also be provided so that the lifting mechanism 27 and/or the cable pull device can be controlled manually by a user.

An interface unit 2 can be gripped, held and deposited by means of the gripping device 7 of the handling device 1. By means of the lifting mechanism 27 and the cable 19, an interface unit 2 can also be moved up and down in a vertical direction by the handling device 1.

In the following, a method according to the invention for picking up an interface unit 2 from a storage device or a test device for testing semiconductors with a handling device 1 according to the embodiment example of the present invention described above is explained.

The handling device 1 moves in space by means of a travel mechanism 3. The travel mechanism 3 is, for example, an AGV or an AMR and has a drive unit to enable it to move autonomously in space. The travel mechanism 3 can receive signals, such as a destination, via a radio or data interface. The travel mechanism 3 orientates itself in space using a camera for spatial vision. A transportable remote control can also be provided, for example, so that the travel mechanism 3 can be controlled manually by a user. Alternatively, the AGV can orientate itself using reflectors mounted in the room.

The handling device 1 approaches the storage device or the test device autonomously or is controlled by a user by means of the travel mechanism 3.

The handling device 1 couples to the storage device or the test device by means of docking elements 21. The storage device and the test device have corresponding counter-docking elements for this purpose. By means of a camera, the handling device 1 automatically finds the correct distance to the storage device or the test device and automatically positions the docking elements 21 exactly in relation to the counter-docking elements of the storage device or the test device.

For exact vertical positioning of the docking elements 21, the handling device 1 has a lifting device 24 with a lifting mechanism 27. The docking elements 21 are mounted on the handling device 1 by means of a swivel joint 21 and for this reason always have an inclination that allows coupling with the counter-docking elements, even if the handling device 1 is standing on a surface 17 that is inclined relative to a receiving area on which the interface unit is to be placed. In this way, the docking elements 21 can be coupled to the counter-docking unit without exerting tension on the handling device 1 and the docking elements 21 can always align themselves automatically with the counter-docking elements.

The docking elements 21 and the counter-docking elements are designed according to the plug/socket principle, with the docking elements 21 forming the plugs and the counter-docking elements forming the sockets. Upon engagement with the counter-docking elements, the docking elements 21 align themselves in the axial direction to the counter-docking elements and are drawn into the counter-docking elements up to a predetermined end position. As a result, the handling device 1 can initially be coupled with the docking elements 21 to the counter-docking elements with a certain amount of play, whereby the docking elements 21 and the counter-docking elements are then drawn together essentially without play, whereby the docking elements 21 are positioned precisely in relation to the counter-docking elements.

If the handling device 1 is coupled to the storage device or the test device, the interface unit 2 is provided by the storage device or the test device at the pick-up area in order to be picked up by the handling device 1.

A cable 19 is used to lower a gripping element 13 with grippers 16 in order to position the grippers 16 on the interface unit 2 in such a way that they can grip and pick up the interface unit 2. The grippers 16 are mechanical grippers that engage laterally on an interface unit 2 in order to detachably couple the interface unit 2 to the gripping element 13. In order to actuate the grippers 16, the gripping element 13 has an actuator 20. The gripping element 13 has guide rails 18 to laterally support and protect the interface unit 2.

After picking up the interface unit 2, the gripping element 13 is retracted by means of the cable 19 and the handling device 1 is released by decoupling the docking elements 21 from the counter-docking elements.

The handling device 1 is removed from the storage device or the test device by means of the travel mechanism 3 and can move freely.

Furthermore, a method according to the invention for transferring an interface unit 2 arranged on grippers 16 of a gripping element 13 of a handling device 1 to a storage device or a test device for testing semiconductors with a handling device 1 according to the embodiment example of the present invention described above is explained. The process of approaching and coupling has already been described in detail previously and is therefore only briefly referred to again below.

The handling device 1 with the interface unit 2 approaches the storage device or the test device autonomously or controlled by a user by means of the travel mechanism 3.

By means of docking elements 21, the handling device 1 couples to corresponding counter-docking elements of the storage device or the test device.

The gripping element 13 with the interface unit 2 is lowered by means of a cable 19 in order to deposit the interface unit 2 on a receiving area of the storage device or the test device. By lowering the gripping element 13 by means of the cable 19, an interface unit 2 held by the gripping element 13 is deposited on the device without pressure, i.e., by its weight alone. The “pressureless” depositing of an interface unit 2 ensures that the interface unit 2 is not damaged when the interface unit 2 is transferred from the handling device 1 to another device.

After the interface unit 2 has been set down, the gripping element 13 is retracted by means of the cable 19 and the handling device 1 is released by decoupling the docking elements 21 from the counter-docking elements.

The handling device 1 is removed from the storage device or the test device by means of the travel mechanism 3 and can move freely.

### LIST OF REFERENCE SYMBOLS

1 Handling device
2 Interface unit
3 Travel mechanism
4 Wheel
5 Base
6 Basic body
7 Gripping device
8 Vertical leg
9 Horizontal leg
10 Rail
11 Gripping element guide unit
12 Swivel joint
13 Grip element
14 Guide hole
15 Guide rod
16 Gripper
17 Surface
18 Guide rail
19 Cable
20 Actuator
21 Docking element
22 Guiding elements
23 Stopper element
24 Lifting device
25 Flexible body/spring
26 Actuating device
27 Lifting mechanism
28 Track
29 Bearing ball
30 Bearing body
31 Bearing stub
32 Spatial direction

1. Handling device for transporting interface units for a test device for testing semiconductors, comprising a travel mechanism with a drive unit or a coupling unit for coupling to such a travel mechanism, which is designed for travelling on a substantially flat surface, a gripping device, which comprises a gripping element guide unit and a gripping element for gripping and holding an interface unit, wherein the gripping element can be lowered or raised by the gripping element guide unit, and
a docking unit for coupling the gripping element guide unit to a corresponding counter-docking unit, wherein the gripping element guide unit of the handling device is mounted by means of a swivel joint.

2. Handling device according to claim 1,
wherein the docking unit comprises two docking elements which are spaced a distance apart.

3. Handling device according to claim 2,
wherein the docking elements are designed in such a way that they align themselves in the axial direction to counter-docking elements when engaging with the corresponding counter-docking elements of the counter-docking unit.

4. Handling device according to claim 2,
wherein the docking elements are designed in such a way that they are drawn into the counter-docking elements in the axial direction up to a predetermined end position when engaging with the corresponding counter-docking elements of the counter-docking unit.

5. Handling device according to claim 1,
wherein a lifting mechanism is provided with which the docking unit and the gripping device on the handling device can be raised or lowered.

6. Handling device according to claim 1,
wherein the handling device is designed with a camera for spatial vision, in particular a stereo camera, and has a control device with which the handling device can automatically approach a device comprising the counter-docking unit, so that the docking unit and the counter-docking unit can engage with one another.

7. Handling device for transporting interface units for a test device for testing semiconductors, comprising
a gripping device for gripping and holding an interface unit, wherein the gripping device has a gripping element which can be moved in the vertical direction for gripping an interface unit, wherein the gripping device has a cable pull with which the gripping element can be lowered or raised.

8. Handling device according to claim 7,
wherein the gripping device comprises the lowerable gripping element and a stationary gripping element guide unit, wherein the lowerable gripping element has at least one guide rod which engages in a corresponding guide hole of the gripping element guide unit.

9. Handling device according to claim 8,
wherein a docking unit of the handling device is attached to the gripping element guide unit, and the gripping element guide unit is mounted on the remaining handling device by means of the swivel joint.

10. Handling device according to claim 78,
wherein the gripping device is designed in such a way that, in the maximum position raised by the cable pull, the gripping element rests against the gripping element guide unit.

11. Handling device according to claim 7,
wherein the gripping element has a gripper which can be actuated by means of an actuator, wherein the actuator can be controlled, for example, via a radio interface, a cable connection or a Bowden cable.

12. Method of picking up an interface unit from a test device for testing semiconductors with a handling device according to claim 1, comprising
approaching of the handling device to the test device,
coupling of docking elements of the handling device to counter-docking elements of the test device,
gripping of the interface unit by means of grippers arranged on a gripping element of the handling device, and
removing of the handling device with an interface unit arranged on it.

13. Method for transferring an interface unit arranged on a gripping element of a handling device to a test device for testing semiconductors with a handling device according to claim 1, comprising approaching of the handling device to the test device,
coupling of docking elements of the handling device to counter-docking elements of the test device,
depositing of the interface unit by means of grippers arranged on the gripping element, and
free movement of the handling device.

14. Method according to claim 12,
wherein the handling device has a cable pull with which the gripping element can be lowered or raised.

15. Method according to claim 13,
wherein the handling device has a cable pull with which the gripping element can be lowered or raised.
